(19) United States
(12) Patent Application Publication
(10) Pub. No.: US 2025/0338595 A1
(43) Pub. Date: Oct. 30, 2025

(54) SEMICONDUCTOR DEVICE WITH FILLING LAYER AND METHOD FOR FABRICATING THE SAME

(71) Applicant: NANYA TECHNOLOGY CORPORATION, NEW TAIPEI CITY (TW)

(72) Inventor: YUAN-YUAN LIN, NEW TAIPEI CITY (TW)

(21) Appl. No.: 18/648,641

(22) Filed: Apr. 29, 2024

(51) Int. Cl. H01L 29/45; H01L 29/40

(52) U.S. Cl. CPC H10D 64/62; H10D 64/01

(57) ABSTRACT

The present application discloses a semiconductor device and a method for fabricating the semiconductor device. The semiconductor device includes a substrate; a conductive structure including a conductive concave layer disposed on the substrate and a conductive filling layer disposed on the conductive concave layer, wherein the conductive concave layer includes a top surface having a V-shaped cross-sectional profile; and a top conductive layer disposed on the conductive structure. The conductive filling layer includes germanium or silicon germanium.

### TECHNICAL FIELD

The present disclosure relates to a semiconductor device and a method for fabricating the semiconductor device, and more particularly, to a semiconductor device with a filling layer and a method for fabricating the semiconductor device with the filling layer.

### DISCUSSION OF THE BACKGROUND

Semiconductor devices are used in various electronic applications, including personal computers, cellular telephones, digital cameras, and other electronic equipment. Sizes of semiconductor devices are continuously decreasing to meet the growing demand for computing power. However, such scaling down presents challenges that are becoming more frequent and impactful. Therefore, there are still challenges to overcome in improving quality, yield, performance and reliability while reducing complexity.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a conductive structure including a conductive concave layer disposed on the substrate, wherein a top surface of the conductive concave layer has a V-shaped cross-sectional profile; a conductive filling layer disposed on the conductive concave layer; a first barrier layer covering sidewalls of the conductive concave layer and the conductive filling layer and covering a bottom surface of the conductive concave layer; and a top conductive layer disposed on the conductive structure. The conductive structure is disposed in the substrate and protrudes from the substrate. A surface of the conductive filling layer is concave with respect to the substrate. The conductive filling layer includes germanium or silicon germanium.

Another aspect of the present disclosure provides a semiconductor device including a stacking structure disposed on a semiconductor substrate; a first sidewall spacer and a second sidewall spacer covering a sidewall of the stacking structure; and a contact plug disposed between a pair of the stacking structures. An air gap is sealed between the first and second sidewall spacers. Topmost ends of the first sidewall spacer, the air gap, the second sidewall spacer, and a top surface of the stacking structure are coplanar. A top portion of the air gap is tapered toward the topmost end of the air gap.

Another aspect of the present disclosure provides a method for fabricating a semiconductor device including providing a substrate; forming an epitaxial layer on the substrate; forming a first dielectric layer on the epitaxial layer; forming a first opening in the first dielectric layer, the epitaxial layer, and the substrate; forming a conductive concave layer in the first opening; forming a conductive filling layer on the conductive concave layer and in the first opening; and forming a top conductive layer on the conductive filling layer. A top surface of the conductive concave layer has a V-shaped cross-sectional profile. The conductive concave layer and the conductive filling layer together form a conductive structure. The conductive filling layer comprises germanium or silicon germanium.

Due to the design of the semiconductor device of the present disclosure, a resistance of the conductive structure may be reduced by employing the conductive filling layer including germanium. As a result, a performance of the semiconductor device may be improved.

The foregoing has outlined rather broadly the features and technical advantages of the present disclosure in order that the detailed description of the disclosure that follows may be better understood. Additional features and advantages of the disclosure will be described hereinafter and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in flowchart diagram form, a method for fabricating a semiconductor device in accordance with one embodiment of the present disclosure.

FIGS. 2 to 10 illustrate, in schematic cross-sectional view diagrams, a process for fabricating a semiconductor device in accordance with one embodiment of the present disclosure.

FIGS. 11 and 12 illustrate, in schematic cross-sectional view diagrams, part of a process for fabricating a semiconductor device in accordance with another embodiment of the present disclosure.

FIGS. 13 to 16 illustrate, in schematic cross-sectional view diagrams, part of a process for fabricating a semiconductor device in accordance with another embodiment of the present disclosure.

FIGS. 17 and 18 illustrate, in schematic cross-sectional view diagrams, part of a process for fabricating a semiconductor device in accordance with another embodiment of the present disclosure.

FIGS. 19 to 25 illustrate, in schematic cross-sectional view diagrams, semiconductor devices in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to the other element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect such meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device that can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the direction opposite to the direction of the arrow of the direction Z.

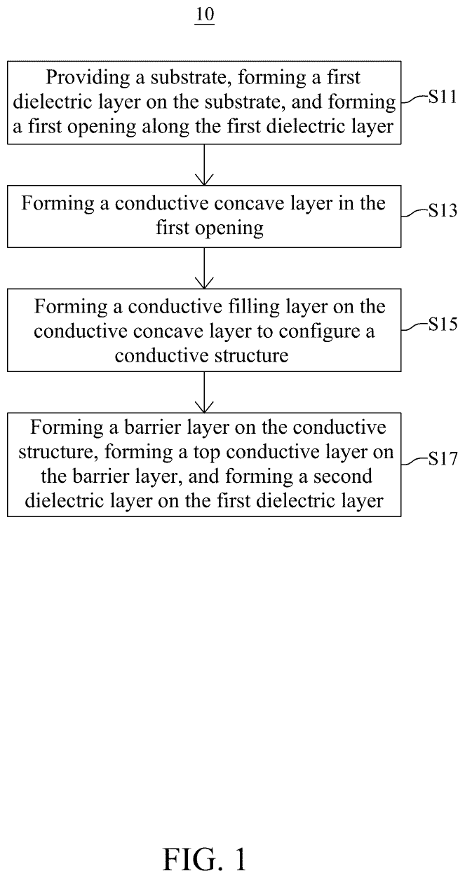

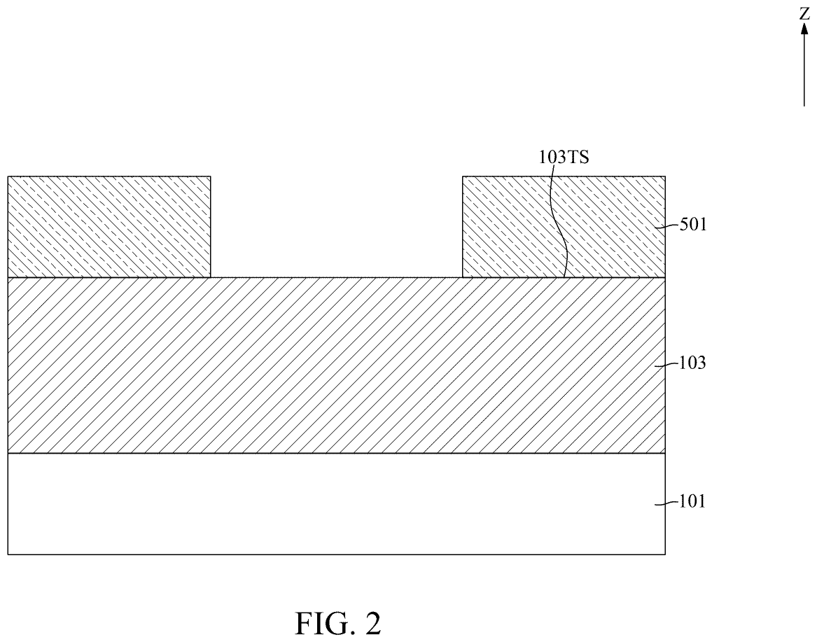

FIG. 1 illustrates, in flowchart diagram form, a method 10 for fabricating a semiconductor device 1A in accordance with one embodiment of the present disclosure. FIGS. 2 to 10 illustrate, in schematic cross-sectional view diagrams, a process for fabricating the semiconductor device 1A in accordance with one embodiment of the present disclosure.

With reference to FIGS. 1 to 3, in step S11, a substrate 101 may be provided, a first dielectric layer 103 may be formed on the substrate 101, and a first opening 103O may be formed in the first dielectric layer 103.

With reference to FIG. 2, the substrate 101 may include a bulk semiconductor substrate that is composed entirely of at least one semiconductor material, a plurality of device elements (not shown for clarity), a plurality of dielectric layers (not shown for clarity), and a plurality of conductive features (not shown for clarity). The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or a combination thereof.

In some embodiments, the substrate 101 may further include a semiconductor-on-insulator structure consisting of, from bottom to top, a handle substrate, an insulator layer, and a topmost semiconductor material layer. The handle substrate and the topmost semiconductor material layer may be formed of the same material as the aforementioned bulk semiconductor substrate. The insulator layer may be a crystalline or non-crystalline dielectric material such as an oxide and/or a nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and either silicon nitride or boron nitride. The insulator layer may have a thickness between about 10 nm and 200 nm.

It should be noted that, in the description of the present disclosure, the term “about,” when used to modify a quantity of an ingredient, component, or reactant of the present disclosure, refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or to carry out the methods, and the like. In one aspect, the term “about” means within 10% of the reported numerical value. In another aspect, the term “about” means within 5% of the reported numerical value. In yet another aspect, the term “about” means within 10%, 9%, 8%, 7%, 6%, 5%, 4%, 3%, 2%, or 1% of the reported numerical value.

The plurality of device elements may be formed on the substrate 101. Some portion of the plurality of device elements may be formed in the substrate 101. The plurality of device elements may be transistors, such as complementary metal-oxide-semiconductor transistors, metal-oxide-semiconductor field-effect transistors, fin field-effect transistors, the like, or a combination thereof.

The plurality of dielectric layers may be formed on the substrate 101 and may cover the plurality of device elements. In some embodiments, the plurality of dielectric layers may be formed of, for example, silicon oxide, borophosphosilicate glass, undoped silicate glass, fluorinated silicate glass, low-k dielectric materials, the like, or a combination thereof. The low-k dielectric materials may have a dielectric constant less than 3.0 or even less than 2.5. In some embodiments, the low-k dielectric materials may have a dielectric constant less than 2.0. The plurality of dielectric layers may be formed by deposition processes such as chemical vapor deposition, plasma-enhanced chemical vapor deposition, or the like. Planarization processes may be performed after the deposition processes to remove excess material and provide a substantially flat surface for subsequent processing steps.

The plurality of conductive features may include interconnect layers, conductive vias, and conductive pads. The interconnect layers may be separated from each other and may be horizontally disposed in the plurality of dielectric layers along the direction Z. In the present embodiment, the topmost interconnect layers may be designated as the conductive pads. The conductive vias may connect adjacent interconnect layers along the direction Z, connect device elements to an adjacent interconnect layer, and/or connect conductive pads to an adjacent interconnect layer. In some embodiments, the conductive vias may improve heat dissipation and may provide structural support. In some embodiments, the plurality of conductive features may be formed of, for example, tungsten, cobalt, zirconium, tantalum, titanium, aluminum, ruthenium, copper, metal carbide (e.g., tantalum carbide, titanium carbide, or tantalum magnesium carbide), metal nitride (e.g., titanium nitride), transition metal aluminides, or a combination thereof. The plurality of conductive features may be formed during the formation of the plurality of dielectric layers.

In some embodiments, the plurality of device elements and the plurality of conductive layers may together comprise functional units of the semiconductor device 1A. In the description of the present disclosure, a functional unit generally refers to functionally related circuitry that has been partitioned for functional purposes into a distinct unit. In some embodiments, the functional units of the semiconductor device 1A may include, for example, highly complex circuits such as processor cores, memory controllers, accelerator units, or other applicable functional circuitry.

With reference to FIG. 2, the first dielectric layer 103 may be formed on the substrate 101. In some embodiments, the first dielectric layer 103 may be part of the plurality of dielectric layers of the substrate 101. In some embodiments, the first dielectric layer 103 may be formed of a dielectric material including oxygen atoms and/or nitrogen atoms. In some embodiments, the first dielectric layer 103 may be formed of, for example, silicon oxide, borophosphosilicate glass, undoped silicate glass, fluorinated silicate glass, low-k dielectric materials such as a spin-on low-k dielectric layer or a chemical vapor deposition low-k dielectric layer, or a combination thereof. In some embodiments, the first dielectric layer 103 may include a self-planarizing material such as a spin-on glass or a spin-on low-k dielectric material such as SiLK™. The use of a self-planarizing dielectric material may eliminate the need to perform a subsequent planarizing step. In some embodiments, the first dielectric layer 103 may be formed by a deposition process including, for example, chemical vapor deposition, plasma-enhanced chemical vapor deposition, evaporation, or spin coating. In some embodiments, a planarization process, such as chemical mechanical polishing, may be performed to provide a substantially flat surface for subsequent processing steps. In the present embodiment, the first dielectric layer 103 is formed of silicon oxide. In some embodiments, the first dielectric layer 103 may consist essentially of silicon oxide.

It should be noted that, in the description of the present disclosure, a feature that “consists essentially of” an identified material comprises greater than 95%, greater than 98%, greater than 99%, or greater than 99.5% of the stated material on an atomic basis.

With reference to FIG. 2, a first mask layer 501 may be formed on the first dielectric layer 103. The first mask layer 501 may have a pattern of the first opening 103O. In some embodiments, the first mask layer 501 may be a photoresist layer.

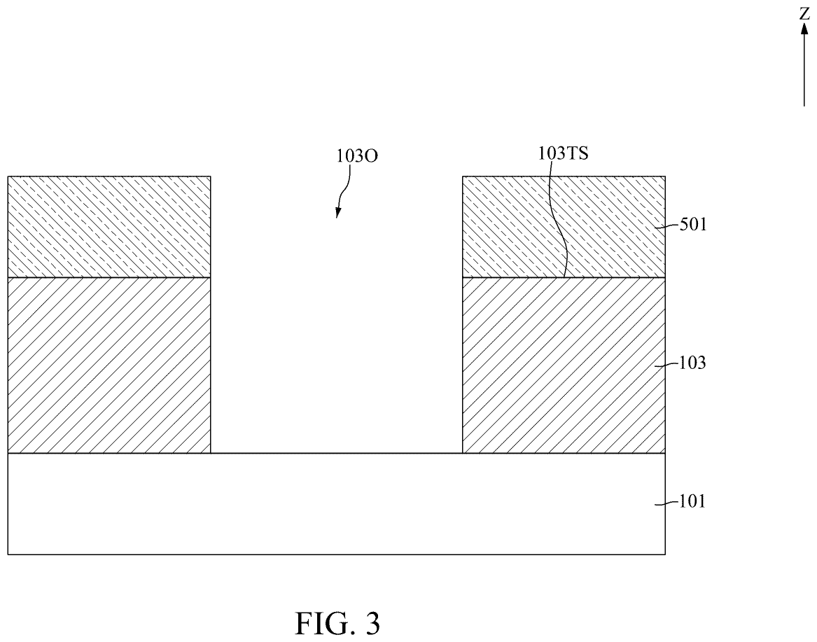

With reference to FIG. 3, an etching process, such as an anisotropic dry etching process, may be performed using the first mask layer 501 as a mask to remove portions of the first dielectric layer 103. In some embodiments, during the etching process, a ratio of an etch rate of the first dielectric layer 103 to an etch rate of the first mask layer 501 may be between about 100:1 and about 1.05:1, between about 15:1 and about 2:1, or between about 10:1 and about 2:1. In some embodiments, during the etching process, a ratio of the etch rate of the first dielectric layer 103 to an etch rate of the substrate 101 may be between about 100:1 and about 1.05:1, between about 15:1 and about 2:1, or between about 10:1 and about 2:1. After the etching process, the first opening 103O may be formed in the first dielectric layer 103. Portions of the substrate 101 may be exposed through the first opening 103O. The first mask layer 501 may be removed after the first opening 103O is formed. In some embodiments, sidewalls of the first opening 103O may be substantially vertical.

It should be noted that, in the description of the present disclosure, a surface is “substantially vertical” if there exists a vertical plane from which the surface does not deviate by more than three times the root mean square roughness of the surface.

With reference to FIGS. 1, 4, and 5, in step S13, a conductive concave layer 201 may be formed in the first opening 103O.

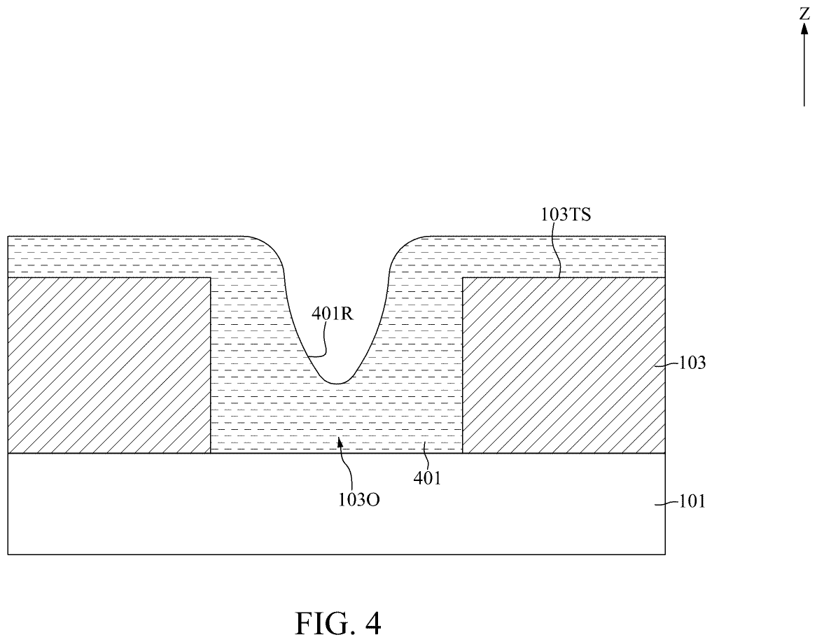

With reference to FIG. 4, a layer of first conductive material 401 may be formed to partially fill the first opening 103O, wherein the layer of first conductive material 401 includes a void 401R and covers a top surface 103TS of the first dielectric layer 103. In other words, the layer of first conductive material 401 may extend along the top surface 103TS of the first dielectric layer 103 and may dip into the first opening 103O to contact the substrate 101. As a scale of the semiconductor device is reduced, a size of the first opening 103O becomes smaller, the layer of first conductive material 401 may not completely fill the first opening 103O, and the void 401R, a boundary of which is concave with respect to the top surface 103TS of the first dielectric layer 103 (or with respect to the substrate 101), may be formed. A portion of the layer of first conductive material 401 may be formed below the void 401R, but the present disclosure is not limited thereto.

In some embodiments, the first conductive material 401 may be a conductive material free of oxygen atoms and/or nitrogen atoms. In some embodiments, the first conductive material 401 may be, for example, polycrystalline silicon, polycrystalline germanium, polycrystalline silicon germanium, doped polycrystalline silicon, doped polycrystalline germanium, or doped polycrystalline silicon germanium. In some embodiments, the layer of first conductive material 401 may be formed by, for example, low-pressure chemical vapor deposition, high-density plasma chemical vapor deposition, or other applicable deposition processes.

In some embodiments, the layer of first conductive material 401 may be deposited by low-pressure chemical vapor deposition. A process pressure for depositing the layer of first conductive material 401 may be between about 0.1 Torr and about 50 Torr. A reaction gas for depositing the layer of first conductive material 401 may include a silicon source gas such as silane and/or a doping gas such as phosphine.

In some embodiments, the layer of first conductive material 401 may be deposited by high-density-plasma chemical vapor deposition. The high-density plasma chemical vapor deposition may employ a plasma having an ion density on the order of 1E11 ions/cm\hat{ }3 or greater. The high-density plasma chemical vapor deposition may also have an ionization fraction (ion/neuclei ratio) on the order of 1E-4 or greater. The high-density-plasma chemical vapor deposition may include a pretreatment operation and a deposition operation.

In some embodiments, the pretreatment operation may include applying a hydrogen plasma to the first opening 103O. The deposition operation may include applying a silicon-source plasma to deposit the layer of first conductive material 401. A bias may be optionally applied during the deposition operation.

In some embodiments, during the pretreatment operation and the deposition operation, the substrate temperature may be below or about 500° C., below or about 450° C., or below or about 400° C. The substrate temperature may be controlled in a variety of ways. For example, the substrate temperature may be raised by a frontside plasma and may be cooled by a backside flow of helium.

In some embodiments, the hydrogen plasma may be generated using a hydrogen source. The hydrogen source may be, for example, hydrogen, ammonia, or hydrazine. In some embodiments, the silicon-source plasma may be generated using a silicon source. The silicon source may be, for example, silane, disilane, or other high-order silanes.

In some embodiments, the hydrogen source and/or the silicon source may be combined with inert gases which may assist in stabilizing the high-density plasma. The inert gases may include argon, neon, and/or helium.

In some embodiments, a source of dopants may also be included during the deposition operation in order to incorporate dopants in the layer of first conductive material 401. The nature of the high-density plasma allows the dopants to bond more tightly within the layer of first conductive material 401 which obviates a need for a separate thermal dopant activation step. In some embodiments, a boron-containing precursor (e.g., triethylborane, trimethylborane, borane, diborane, or higher-order boranes) may be used as the source of dopants in order to dispose activated boron doping centers in the layer of first conductive material 401. In some embodiments, a phosphorus-containing precursor (e.g., phosphine) may be used as the source of dopants in order to dispose activated phosphorus doping centers in the layer of first conductive material 401.

In some embodiments, the void 401R may have a U-shaped cross-sectional profile or a V-shaped cross-sectional profile. In other words, a top surface of the layer of first conductive material 401 formed in the first opening 103O, which forms the void 401R, may have a U-shaped cross-sectional profile or a V-shaped cross-sectional profile.

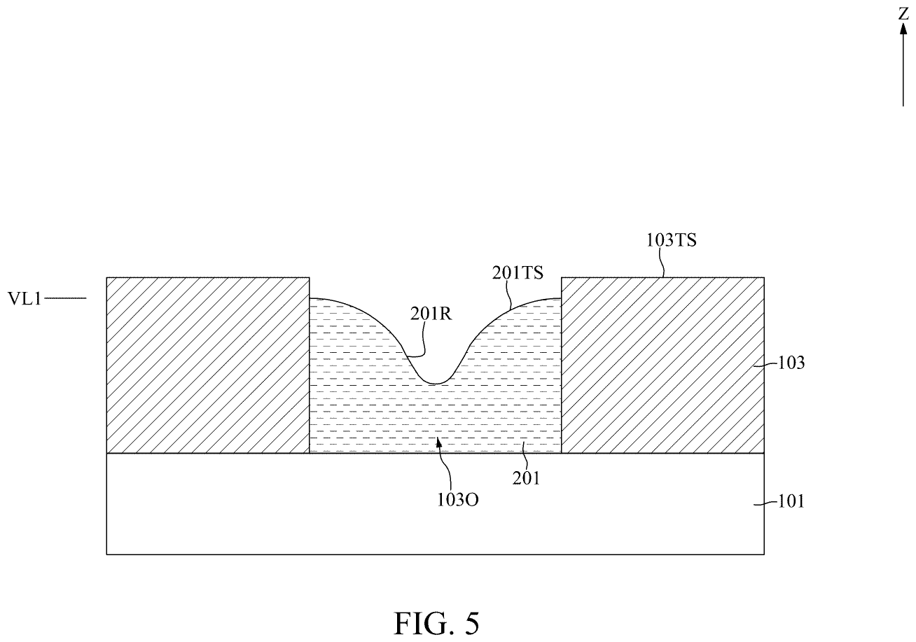

With reference to FIG. 5, an etch-back process may be performed to remove a portion of the first conductive material 401. In some embodiments, during the etch-back process, a ratio of an etch rate of the first conductive material 401 to an etch rate of the first dielectric layer 103 may be between about 100:1 and about 1.05:1, between about 15:1 and about 2:1, or between about 10:1 and about 2:1. After the etch-back process, a remaining portion of first conductive material 401 may be referred to as the conductive concave layer 201. The void 401R may be turned into a recess 201R of the conductive concave layer 201, wherein the recess 201R may be referred to as part of a top surface 201TS of the conductive concave layer 201. In some embodiments, the recess 201R may have a U-shaped cross-sectional profile or a V-shaped cross-sectional profile. In other words, the top surface 201TS of the conductive concave layer 201, which forms the recess 201R, may have a U-shaped cross-sectional profile or a V-shaped cross-sectional profile. The top surface 201TS of the conductive concave layer 201 may be at a vertical level VL1 lower than the top surface 103TS of the first dielectric layer 103. A part of the top surface 201TS (i.e., the recess 201R) may be concave with respect to the substrate 101.

With reference to FIGS. 1, 6, and 7, in step S15, a conductive filling layer 203 may be deposited on the conductive concave layer 201 to form a conductive structure 200.

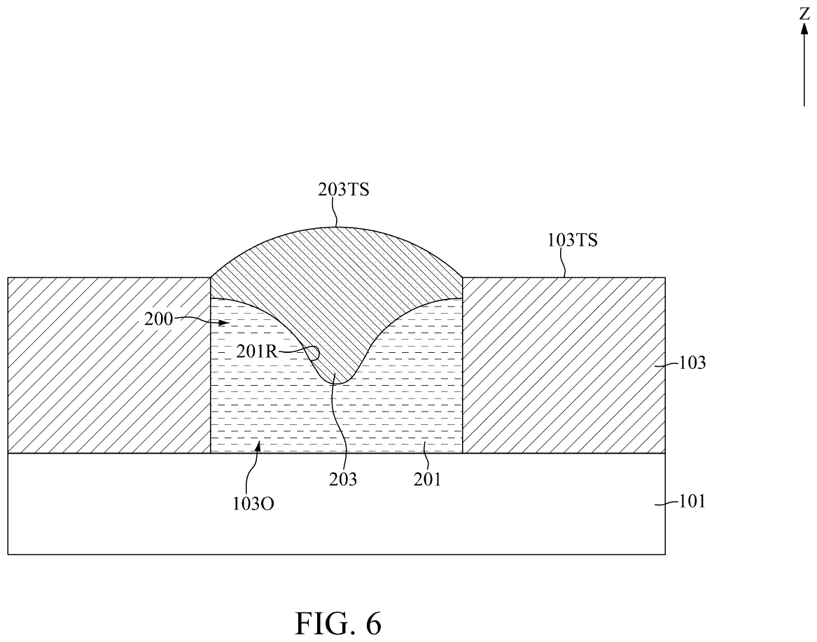

With reference to FIG. 6, the conductive filling layer 203 may be selectively deposited on the conductive concave layer 201. In the current stage, a top surface 203TS of the conductive filling layer 203 may protrude from the top surface 103TS of the first dielectric layer 103. In other words, the top surface 203TS of the conductive filling layer 203 may be convex with respect to the top surface 103TS of the first dielectric layer 103 (or with respect to the substrate 101).

In some embodiments, the conductive filling layer 203 may be formed of, for example, germanium. In some embodiments, the conductive filling layer 203 may include an atomic percentage of germanium greater than or equal to 50%. In this regard, the conductive filling layer 203 may be described as a “germanium-rich layer.” In some embodiments, the atomic percentage of germanium in the conductive filling layer 203 may be greater than or equal to 60%, greater than or equal to 70%, greater than or equal to 80%, greater than or equal to 90%, greater than or equal to 95%, greater than or equal to 98%, greater than or equal to 99%, or greater than or equal to 99.5%. In other words, in some embodiments, the conductive filling layer 203 consists essentially of germanium. In some embodiments, the conductive filling layer 203 may include silicon and germanium. In other words, in some embodiments, the conductive filling layer 203 may include silicon germanium.

In some embodiments, the conductive filling layer 203 may be formed by a deposition process. In some embodiments, the deposition process may include a reactive gas including a germanium precursor and/or hydrogen gas. In some embodiments, the germanium precursor may consist essentially of germane. In some embodiments, the germanium precursor may include one or more of germane, digermane, isobutylgermane, chlorogermane, or dichlorogermane. In some embodiments, the hydrogen gas may be used as a carrier or diluent for the germanium precursor. In some embodiments, the reactive gas may consist essentially of germane and hydrogen gas. In some embodiments, the molar percentage of germane in the reactive gas may be in a range of about 1% to about 50%, in a range of about 2% to about 30%, or in a range of about 5% to about 20%.

Alternatively, in some embodiments, the reactive gas may further include a silicon-containing precursor. In some embodiments, the silicon-containing precursor may include one or more of silane, a polysilane, or a halosilane. As used in this regard, a “polysilane” is a species with the general formula SiₙH₂ₙ₊₂ where n is between 2 and 6. Further, a “halosilane” is a species with the general formula SiₐX_{b}H_{2a+2-b} where X is a halogen, a is between 1 and 6, and b is between 1 and 2a+2. In some embodiments, the silicon-containing precursor comprises one or more of SiH₄, Si₂H₆, Si₃H₈, Si₄H₁₀, SiCl₄, or SiH₂Cl₂.

In some embodiments, a temperature of the intermediate semiconductor device to be deposited may be maintained during the deposition process. The temperature may be referred to as the substrate temperature. In some embodiments, the substrate temperature may be in a range between about 300° C. and about 800° C., between about 400° C. and about 800° C., between about 500° C. and about 800° C., between about 250° C. and about 600° C., between about 400° C. and about 600° C., or between about 500° C. and about 600° C. In some embodiments, the substrate temperature may be about 540° C.

In some embodiments, a pressure of the processing chamber for depositing the conductive filling layer 203 may be maintained during the deposition process. In some embodiments, the pressure is maintained in a range between about 1 Torr and about 300 Torr, between about 10 Torr and about 300 Torr, between about 50 Torr and about 300 Torr, between about 100 Torr and about 300 Torr, between about 200 Torr and about 300 Torr, or between about 1 Torr and about 20 Torr. In some embodiments, the pressure may be maintained at about 13 Torr.

In some embodiments, a selectivity of the deposition may be greater than or equal to 5, greater than or equal to 10, greater than or equal to 20, greater than or equal to 30, or greater than or equal to 50. In some embodiments, the deposition of the conductive filling layer 203 on the conductive concave layer 201 may be performed until deposition is observed on the first dielectric layer 103.

It should be noted that, in the description of the present disclosure, the term “selectively depositing a layer on a first feature over a second feature,” and the like, means that a first amount of the layer is deposited on the first feature and a second amount of the layer is deposited on the second feature, wherein the first amount of the layer is greater than the second amount of the layer, or no layer is deposited on the second feature. The selectivity of a deposition process may be expressed as a multiple of growth rate. For example, if a deposition on one surface occurs twenty-five times faster than the deposition on a different surface, the process can be described as having a selectivity of 25:1 or simply 25. In this regard, higher ratios indicate more selective deposition processes.

The term “over” used in this regard does not imply a physical orientation of one feature on top of another feature, but rather indicates a relationship of thermodynamic or kinetic properties of a chemical reaction with one feature relative to the other feature. For example, selectively depositing a germanium layer onto a silicon surface over a dielectric surface means that the germanium layer is deposited more rapidly on the silicon surface and less rapidly or not at all on the dielectric surface; or that the formation of a germanium layer on the silicon surface is thermodynamically or kinetically favorable relative to the formation of a germanium layer on the dielectric surface.

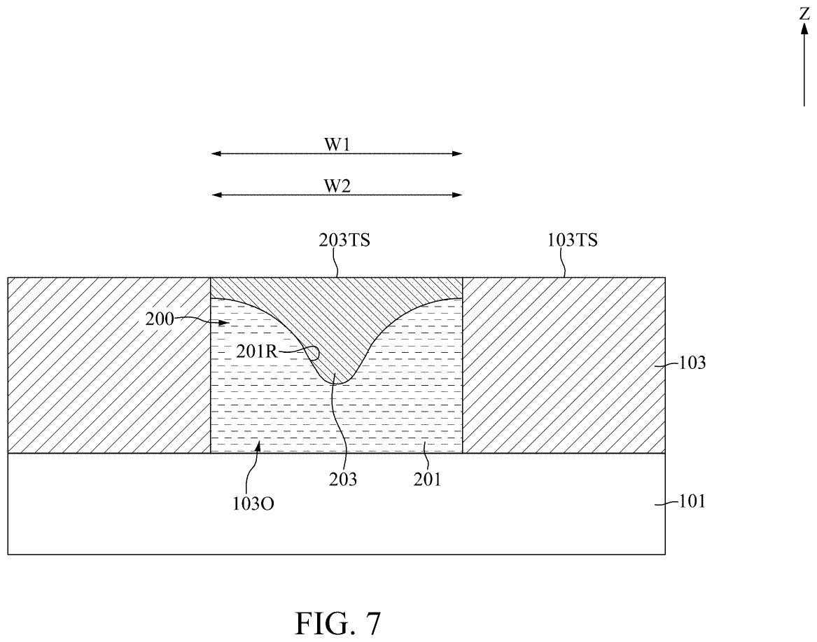

With reference to FIG. 7, a planarization process, such as chemical mechanical polishing, may be performed on the conductive filling layer 203 to remove excess material and provide a substantially flat surface for subsequent processing steps. In the current stage, the top surface 203TS of the conductive filling layer 203 may be substantially coplanar with the top surface 103TS of the first dielectric layer 103. In some embodiments, a width W1 of the conductive concave layer 201 and a width W2 of the conductive filling layer 203 may be substantially the same.

With reference to FIG. 1 and FIGS. 8 to 10, in step S17, a barrier layer 105 may be formed on the conductive structure 200, a top conductive layer 107 may be formed on the barrier layer 105, and a second dielectric layer 109 may be formed on the first dielectric layer 103.

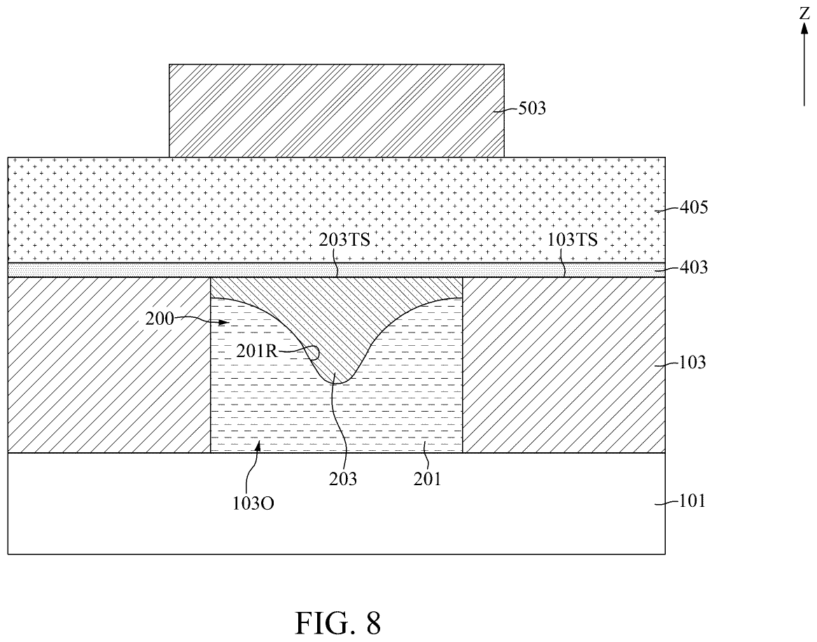

With reference to FIG. 8, a layer of barrier material 403 may be formed on the first dielectric layer 103 and the conductive structure 200. In some embodiments, the barrier material 403 may be formed of, for example, titanium, titanium nitride, tantalum, tantalum nitride, or a combination thereof. In some embodiments, the layer of barrier material 403 may be a multi-layer structure. For example, the layer of barrier material 403 may be a titanium/titanium nitride bi-layer or a tantalum/tantalum nitride bi-layer. In some embodiments, the layer of barrier material 403 may be formed by, for example, chemical vapor deposition, atomic layer deposition, or other applicable deposition processes.

For example, when the barrier material 403 is titanium nitride, the layer of barrier material 403 may be formed by chemical vapor deposition. In some embodiments, a formation of the layer of barrier material 403 may include a source gas introduction step, a first purging step, a reactant flowing step, and a second purging step. The source gas introduction step, the first purging step, the reactant flowing step, and the second purging step may be referred to as one cycle. Multiple cycles may be performed to obtain a desired thickness of the layer of barrier material 403.

In some embodiments, an intermediate semiconductor device as shown in FIG. 7 may be loaded into a reaction chamber. In the source gas introduction step, source gases containing a precursor and a reactant may be introduced into the reaction chamber containing the intermediate semiconductor device. The precursor and the reactant may diffuse and reach a surface of the intermediate semiconductor device (i.e., the top surface 103TS of the first dielectric layer 103 and the top surface 203TS of the conductive filling layer 203). The precursor and the reactant may adsorb on and subsequently migrate on the surface of the intermediate semiconductor device. The adsorbed precursor and the adsorbed reactant may react on the surface and form solid by-products. The solid by-products may form nuclei on the surface. The nuclei may grow into islands and the islands may merge into a continuous thin film on the surface. In the first purging step, a purge gas such as argon may be injected into the reaction chamber to purge out the gaseous by-products, unreacted precursor, and unreacted reactant.

In the reactant flowing step, the reactant may be solely introduced into the reaction chamber to turn the continuous thin film into the layer of barrier material 403. In the second purging step, a purge gas such as argon may be injected into the reaction chamber to purge out the gaseous by-products and unreacted reactant.

In some embodiments, a formation of the layer of barrier material 403 using chemical vapor deposition may be performed with the assistance of plasma. The source of the plasma may be, for example, argon, hydrogen, or a combination thereof.

For example, the precursor may be titanium tetrachloride. The reactant may be ammonia. Titanium tetrachloride and ammonia may react on the surface of the intermediate semiconductor device and form a titanium nitride film including high chloride contamination due to incomplete reaction between titanium tetrachloride and ammonia. The ammonia in the reactant flowing step may reduce the chloride content of the titanium nitride film. After the ammonia treatment, the titanium nitride film may be referred to as the layer of barrier material 403.

With reference to FIG. 8, in some other embodiments, the layer of barrier material 403 may be formed by atomic layer deposition such as photo-assisted atomic layer deposition or liquid injection atomic layer deposition. In some embodiments, formation of the layer of barrier material 403 may include a first precursor introduction step, a first purging step, a second precursor introduction step, and a second purging step. The first precursor introduction step, the first purging step, the second precursor introduction step, and the second purging step may be referred to as one cycle. Multiple cycles may be performed to obtain a desired thickness of the layer of barrier material 403.

In some embodiments, an intermediate semiconductor device as shown in FIG. 7 may be loaded into the reaction chamber. In the first precursor introduction step, a first precursor may be introduced into the reaction chamber. The first precursor may diffuse and reach the surface of the intermediate semiconductor device (i.e., the top surface 103TS of the first dielectric layer 103 and the top surface 203TS of the conductive filling layer 203). The first precursor may adsorb on the surface of the intermediate semiconductor device to form a monolayer at a single atomic layer level. In the first purging step, a purge gas such as argon may be injected into the reaction chamber to purge out the unreacted first precursor.

In the second precursor introduction step, a second precursor may be introduced into the reaction chamber. The second precursor may react with the monolayer and turn the monolayer into the layer of barrier material 403. In the second purging step, a purge gas such as argon may be injected into the reaction chamber to purge out unreacted second precursor and gaseous by-product. In contrast to the chemical vapor deposition, the atomic layer deposition allows suppression of a particle generation caused by a gas phase reaction because the first precursor and the second precursor are separately introduced.

In some embodiments, the first precursor may be titanium tetrachloride. The second precursor may be ammonia. Adsorbed titanium tetrachloride may form a titanium nitride monolayer. The ammonia in the second precursor introduction step may react with the titanium nitride monolayer and turn the titanium nitride monolayer into the layer of barrier material 403.

In some embodiments, formation of the layer of barrier material 403 using atomic layer deposition may be performed with the assistance of plasma. The source of the plasma may be, for example, argon, hydrogen, oxygen, or a combination thereof. In some embodiments, the oxygen source may be, for example, water, oxygen gas, or ozone. In some embodiments, co-reactants may be introduced into the reaction chamber. The co-reactants may be selected from the group consisting of hydrogen, hydrogen plasma, oxygen, air, water, ammonia, hydrazines, alkylhydrazines, boranes, silanes, ozone and combination thereof.

In some embodiments, formation of the layer of barrier material 403 may be performed under the following process conditions. Substrate temperature may be between about 160° C. and about 300° C. Evaporator temperature may be about 175° C. The pressure of the reaction chamber may be about 5 mbar. A solvent of the first precursor and the second precursor may be toluene.

With reference to FIG. 8, a layer of second conductive material 405 may be formed on the layer of barrier material 403. In some embodiments, the second conductive material 405 may be, for example, aluminum, tungsten, copper, or a combination thereof. In some embodiments, the layer of second conductive material 405 may be formed by, for example, chemical vapor deposition, physical vapor deposition, electroplating, electroless plating, or other applicable deposition processes.

With reference to FIG. 8, a second mask layer 503 may be formed on the layer of second conductive material 405. The second mask layer 503 may include a pattern of the top conductive layer 107. In some embodiments, the second mask layer 503 may be a photoresist layer.

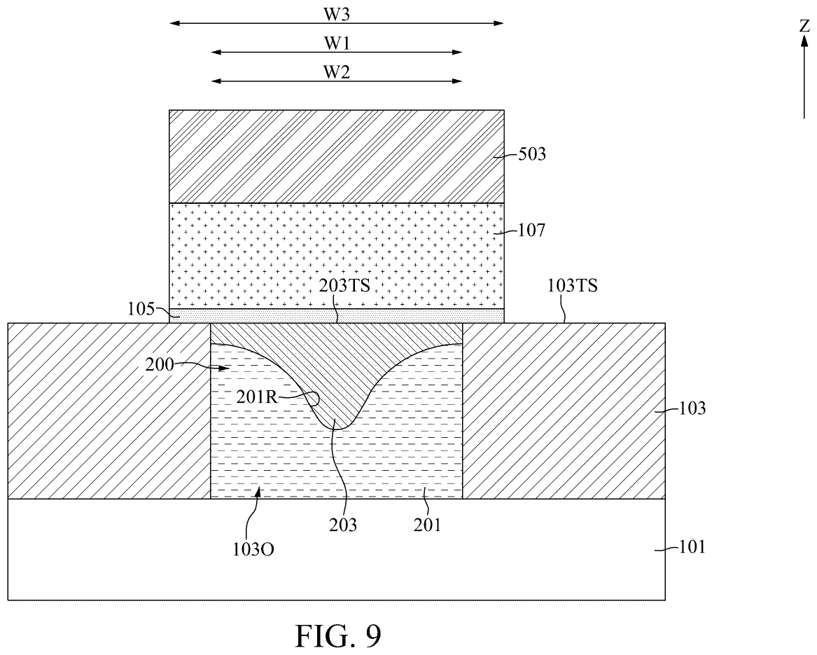

With reference to FIG. 9, an etching process may be performed to remove portions of the barrier material 403 and the second conductive material 405 using the second mask layer 503 as a mask. After the etching process, remaining portions of the barrier material 403 may be referred to as the barrier layer 105. Remaining portions of the second conductive material 405 may be referred to as the top conductive layer 107. In some embodiments, the etching process may be a multi-stage etching process. For example, the etching process may be a two-stage etching process. In some embodiments, during the etching process, a ratio of an etch rate of the second conductive material 405 to an etch rate of the second mask layer 503 may be between about 100:1 and about 1.05:1, between about 15:1 and about 2:1, or between about 10:1 and about 2:1. In some embodiments, during the etching process, a ratio of the etch rate of the second conductive material 405 to an etch rate of the barrier material 403 may be between about 100:1 and about 1.05:1, between about 15:1 and about 2:1, or between about 10:1 and about 2:1. In some embodiments, during the etching process, a ratio of the etch rate of the barrier material 403 to an etch rate of the first dielectric layer 103 may be between about 100:1 and about 1.05:1, between about 15:1 and about 2:1, or between about 10:1 and about 2:1. After the etching process, the second mask layer 503 may be removed.

With reference to FIG. 9, a width W3 of the barrier layer 105 or the top conductive layer 107 may be greater than the width W1 of the conductive concave layer 201 or greater than the width W2 of the conductive filling layer 203.

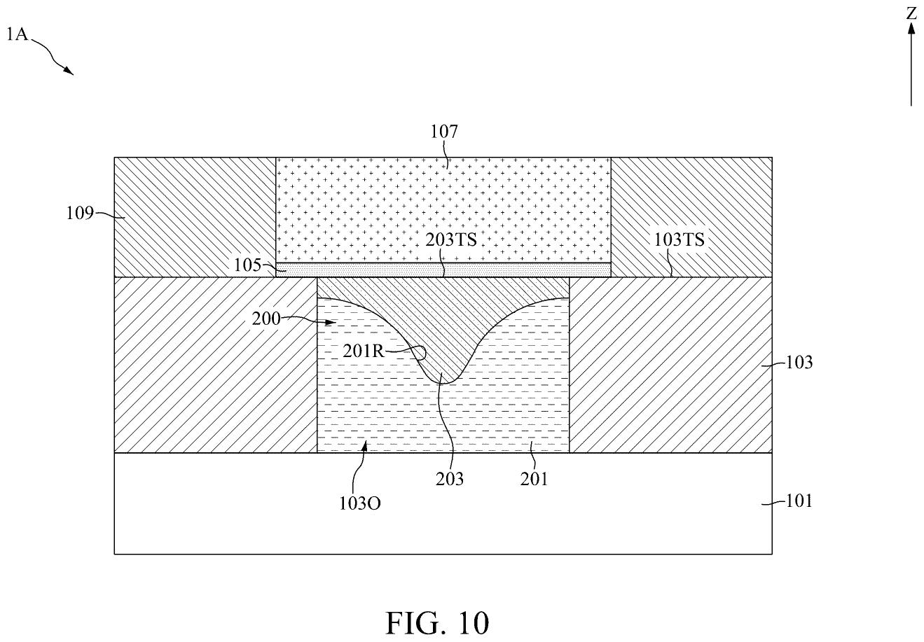

With reference to FIG. 10, a second dielectric layer 109 may be formed on the first dielectric layer 103 and may cover the top conductive layer 107. A planarization process, such as chemical mechanical polishing, may be performed until a top surface of the top conductive layer 107 is exposed to remove excess material and provide a substantially flat surface for subsequent processing steps. In some embodiments, the second dielectric layer 109 may be formed of, for example, silicon dioxide, undoped silicate glass, fluorosilicate glass, borophosphosilicate glass, a spin-on low-k dielectric layer, a chemical vapor deposition low-k dielectric layer, or a combination thereof. In some embodiments, the second dielectric layer 109 may be formed by a deposition process including, for example, chemical vapor deposition, plasma-enhanced chemical vapor deposition, evaporation, spin coating, or other applicable deposition processes. In some embodiments, the second dielectric layer 109 and the first dielectric layer 103 may be formed of a same material. In some embodiments, the second dielectric layer 109 and the first dielectric layer 103 may be formed of different materials.

Due to the conductive filling layer 203, a resistance of the conductive structure 200 may be reduced. As a result, performance of the semiconductor device 1A may be improved.

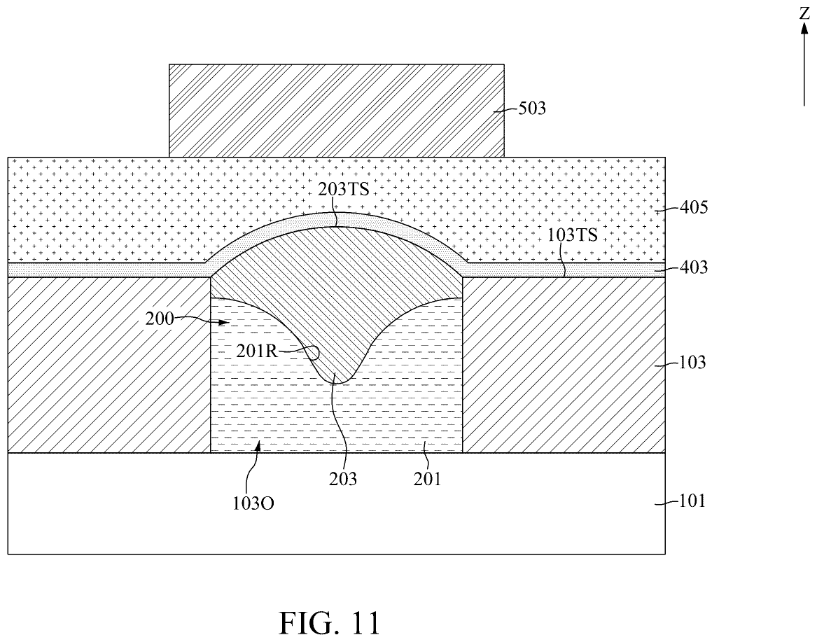

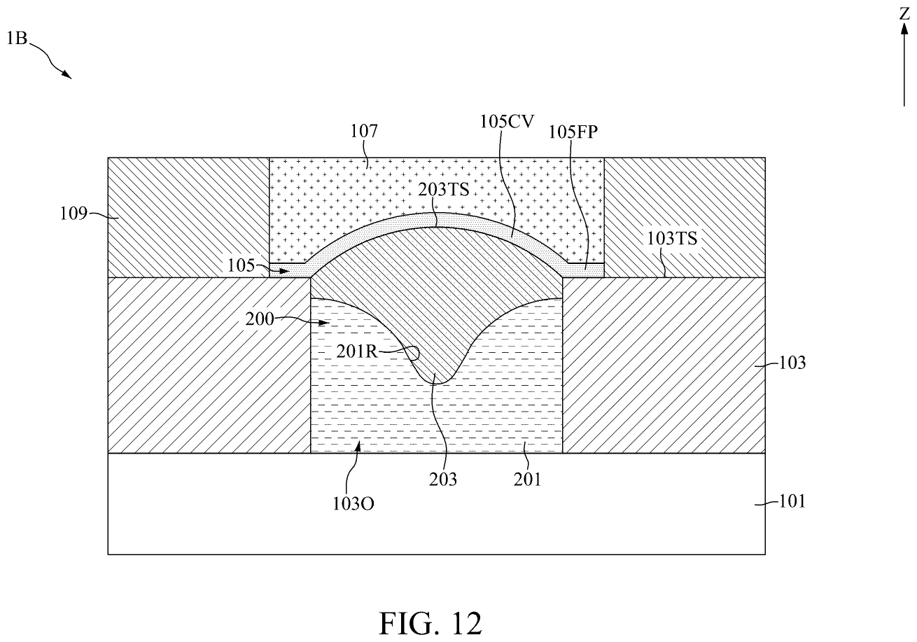

FIGS. 11 and 12 illustrate, in schematic cross-sectional view diagrams, part of a process for fabricating a semiconductor device 1B in accordance with another embodiment of the present disclosure.

With reference to FIG. 11, an intermediate semiconductor device may be fabricated by a procedure similar to that illustrated in FIGS. 2 to 6, and descriptions thereof are not repeated herein. It should be noted that, in the fabrication of the semiconductor device 1B, no planarization process is performed on the conductive filling layer 203. As a result, the top surface 203TS of the conductive filling layer 203 is convex with respect to the top surface 103TS of the first dielectric layer 103 or with respect to the substrate 101. The layer of barrier material 403 may be formed directly on the conductive filling layer 203 and the first dielectric layer 103 by a procedure similar to that illustrated in FIG. 8, and descriptions thereof are not repeated herein. Because no planarization process is performed on the conductive filling layer 203, a portion of the layer of barrier material 403 formed on the conductive filling layer 203 may also be convex with respect to the top surface 103TS of the first dielectric layer 103 or with respect to the substrate 101.

With reference to FIG. 11, the layer of second conductive material 405 may be formed on the layer of barrier material 403 by a procedure similar to that illustrated in FIG. 8, and descriptions thereof are not repeated herein. A planarization process, such as chemical mechanical polishing, may be performed on the layer of second conductive material 405 to remove excess materials and provide a substantially flat surface for subsequent processing steps. The second mask layer 503 may be formed on the layer of second conductive material 405 by a procedure similar to that illustrated in FIG. 8, and descriptions thereof are not repeated herein.

With reference to FIG. 12, the barrier layer 105 and the top conductive layer 107 may be formed by a procedure similar to that illustrated in FIG. 9, and descriptions thereof are not repeated herein. The second dielectric layer 109 may be formed by a procedure similar to that illustrated in FIG. 10, and descriptions thereof are not repeated herein.

With reference to FIG. 12, the top surface 203TS of the conductive filling layer 203 may be convex with respect to the top surface 103TS of the first dielectric layer 103 or with respect to the substrate 101. The barrier layer 105 may include a convex portion 105CV and two flat portions 105FP. The convex portion 105CV may be conformally formed on the top surface 203TS of the conductive filling layer 203. The two flat portions 105FP may extend from two ends of the convex portion 105CV and may be conformally formed on the top surface 103TS of the first dielectric layer 103.

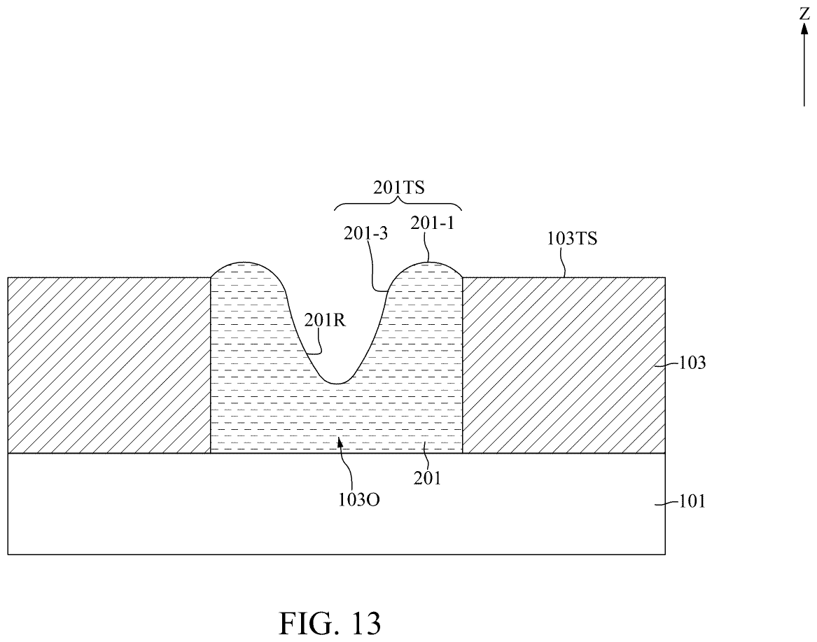

FIGS. 13 to 16 illustrate, in schematic cross-sectional view diagrams, part of a process for fabricating a semiconductor device 1C in accordance with another embodiment of the present disclosure.

With reference to FIG. 13, an intermediate semiconductor device may be fabricated by a procedure similar to that illustrated in FIGS. 2 to 6, and descriptions thereof are not repeated herein. A planarization process may be performed until the top surface 103TS of the first dielectric layer 103 is exposed. After the planarization process, the recess 201R may remain in the conductive concave layer 201, and a first portion 201-1 of the top surface 201TS of the conductive concave layer 201 may be formed around the recess 201R and adjacent to the first dielectric layer 103. The first portion 201-1 of the top surface 201TS of the conductive concave layer 201 may have a convex surface with respect to the top surface 103TS of the first dielectric layer 103 or with respect to the substrate 101. In other words, the first portion 201-1 of the top surface 201TS of the conductive concave layer 201 may protrude from the top surface 103TS of the first dielectric layer 103. A surface of the recess 201R may correspond to a second portion 201-3 of the top surface 201TS of the conductive concave layer 201. The second portion 201-3 of the top surface 201TS of the conductive concave layer 201 may extend from the first portion 201-1 of the top surface 201TS of the conductive concave layer 201 and has a concave shape with respect to the top surface 103TS of the first dielectric layer 103 (or with respect to the substrate 101).

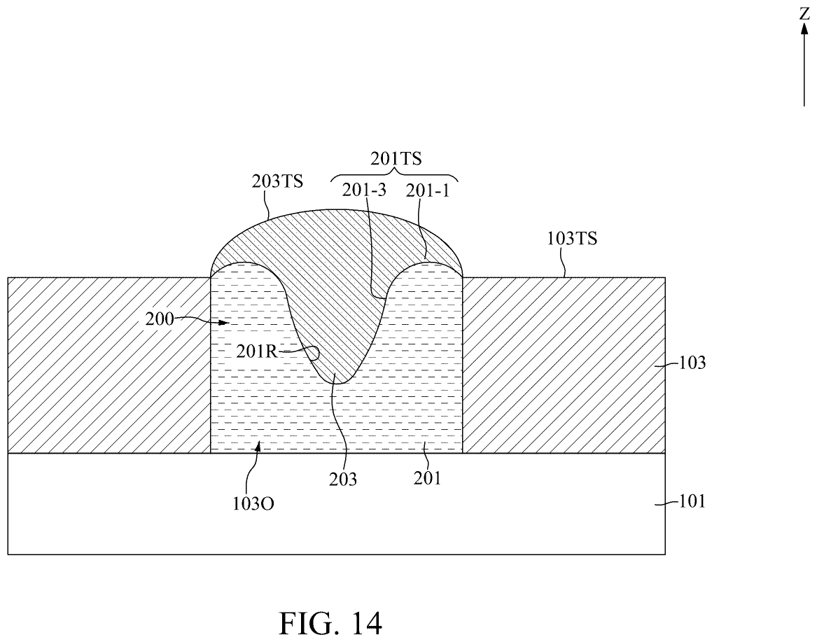

With reference to FIG. 14, the conductive filling layer 203 may be formed on the conductive concave layer 201 by a procedure similar to that illustrated in FIG. 6, and descriptions thereof are not repeated herein. In the current stage, the top surface 203TS of the conductive filling layer 203 may protrude from the top surface 103TS of the first dielectric layer 103. In other words, the top surface 203TS of the conductive filling layer 203 may be convex with respect to the top surface 103TS of the first dielectric layer 103 (or with respect to the substrate 101).

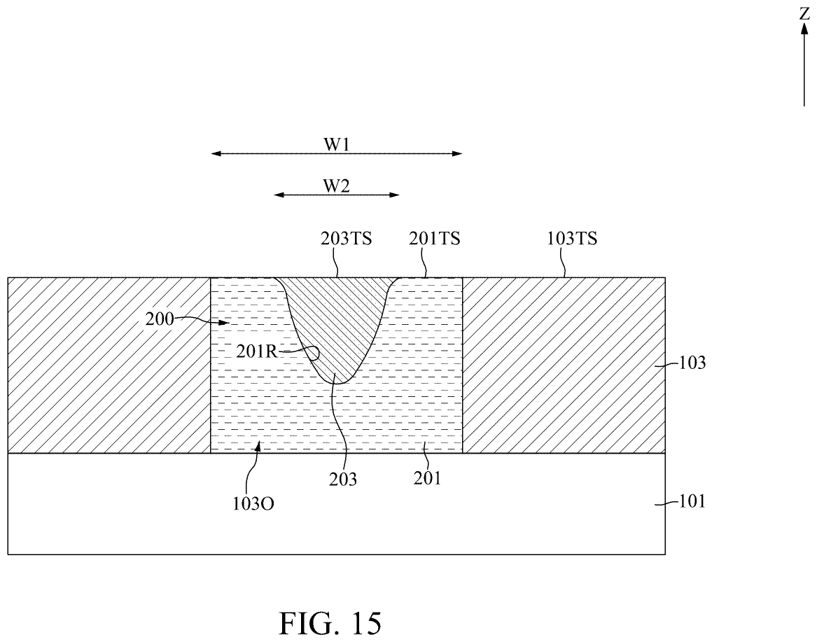

With reference to FIG. 15, a planarization process, such as chemical mechanical polishing, may be performed to remove excess material and provide a substantially flat surface for subsequent processing steps. After the planarization process, the top surface 203TS of the conductive filling layer 203 may be substantially coplanar with the top surface 103TS of the first dielectric layer 103. In some embodiments, the top surface 201TS of the conductive concave layer 201 may be substantially coplanar with the top surface 203TS of the conductive filling layer 203. In some embodiments, a width W1 of the conductive concave layer 201 may be greater than a width W2 of the conductive filling layer 203.

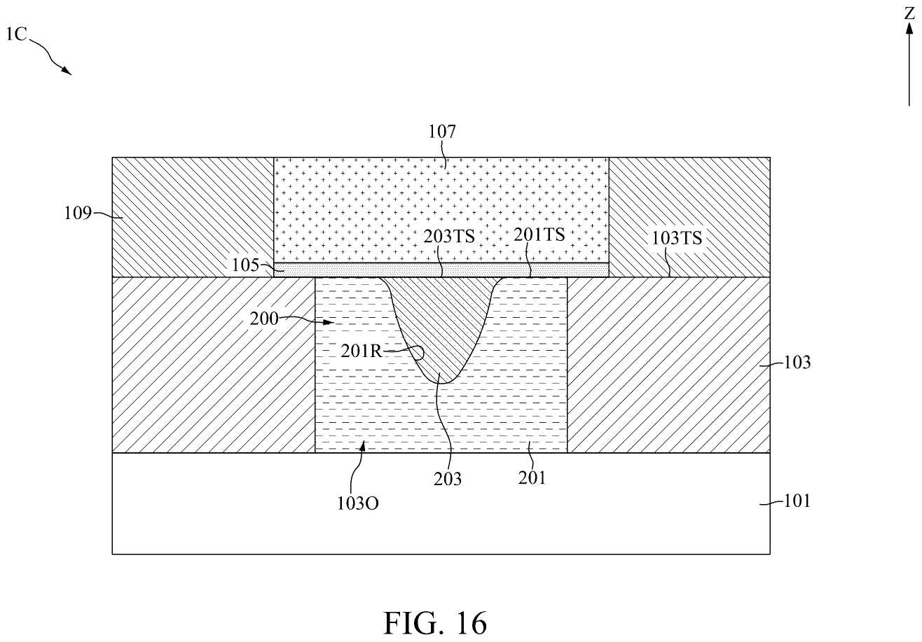

With reference to FIG. 16, the barrier layer 105, the top conductive layer 107, and the second dielectric layer 109 may be formed by a procedure similar to that illustrated in FIGS. 8 to 10, and descriptions thereof are not repeated herein.

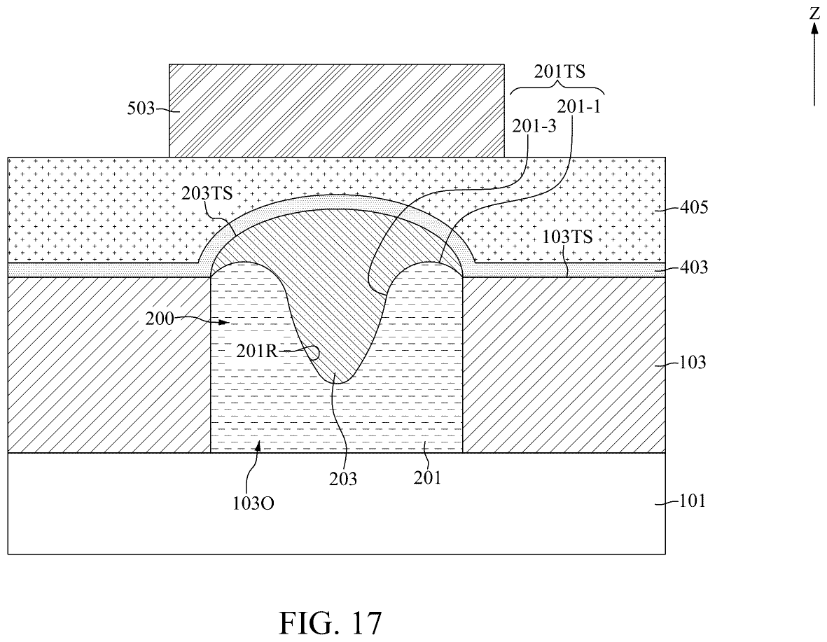

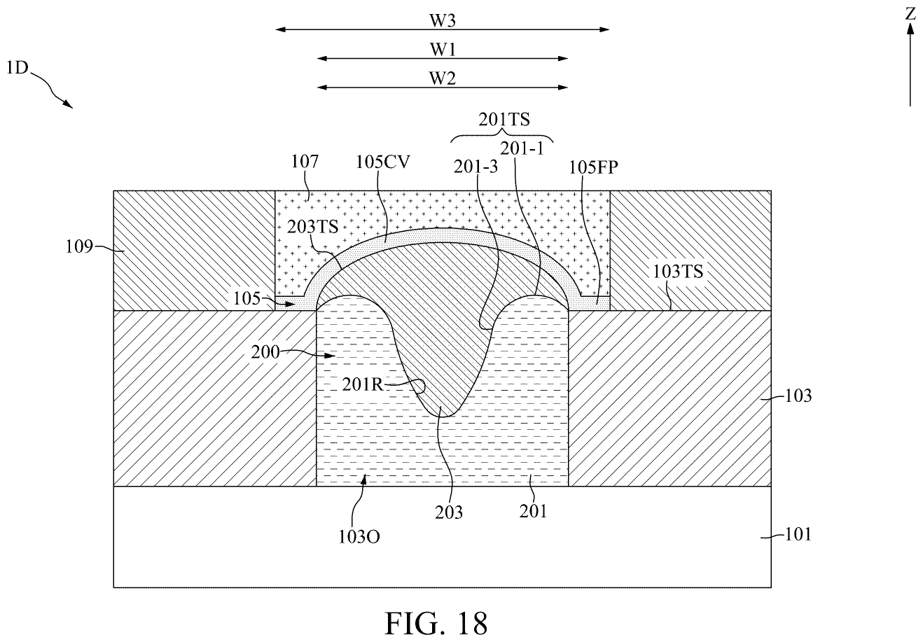

FIGS. 17 and 18 illustrate, in schematic cross-sectional view diagrams, part of a process for fabricating a semiconductor device 1D in accordance with another embodiment of the present disclosure.

With reference to FIG. 17, an intermediate semiconductor device may be fabricated by a procedure similar to that illustrated in FIGS. 13 and 14, and descriptions thereof are not repeated herein. It should be noted that no planarization process is performed on the conductive filling layer 203. As a result, the top surface 203TS of the conductive filling layer 203 is convex with respect to the top surface 103TS of the first dielectric layer 103 or with respect to the substrate 101. The layer of barrier material 403 may be formed directly on the conductive filling layer 203 and the first dielectric layer 103 by a procedure similar to that illustrated in FIG. 8, and descriptions thereof are not repeated herein. Because no planarization process is performed on the conductive filling layer 203, a portion of the layer of barrier material 403 formed on the conductive filling layer 203 may also be convex with respect to the top surface 103TS of the first dielectric layer 103 or with respect to the substrate 101.

With reference to FIG. 17, the layer of second conductive material 405 may be formed on the layer of barrier material 403 by a procedure similar to that illustrated in FIG. 8, and descriptions thereof are not repeated herein. A planarization process, such as chemical mechanical polishing, may be performed to remove excess material and provide a substantially flat surface for subsequent processing steps. The second mask layer 503 may be formed on the layer of second conductive material 405 by a procedure similar to that illustrated in FIG. 8, and descriptions thereof are not repeated herein.

With reference to FIG. 18, the barrier layer 105 and the top conductive layer 107 may be formed by a procedure similar to that illustrated in FIG. 9, and descriptions thereof are not repeated herein. The second dielectric layer 109 may be formed by a procedure similar to that illustrated in FIG. 10, and descriptions thereof are not repeated herein.

With reference to FIG. 18, the barrier layer 105 may include a convex portion 105CV and two flat portions 105FP. The convex portion 105CV may be conformally formed on the top surface 203TS of the conductive filling layer 203. The conductive filling layer 203 may be convex with respect to the top surface 103TS of the first dielectric layer 103 or with respect to the substrate 101. The two flat portions 105FP may extend from two ends of the convex portion 105CV and may be conformally formed on the top surface 103TS of the first dielectric layer 103. In some embodiments, the width W3 of the barrier layer 105 or the top conductive layer 107 may be greater than the width W1 of the conductive concave layer 201 or greater than the width W2 of the conductive filling layer 203. In some embodiments, the width W1 of the conductive concave layer 201 and the width W2 of the conductive filling layer 203 may be substantially the same.

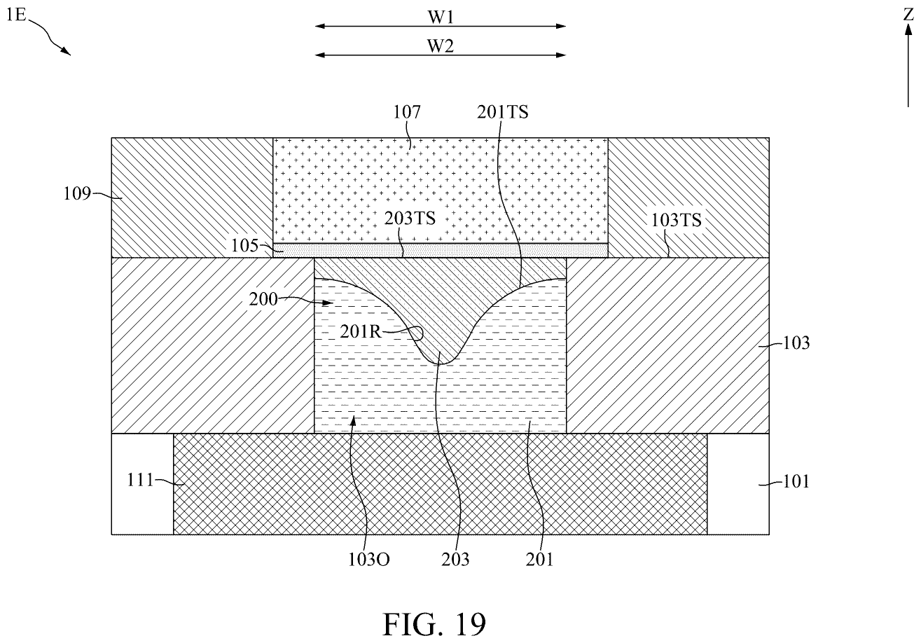

FIGS. 19 to 23 illustrate, in schematic cross-sectional view diagrams, semiconductor devices 1E, 1F, 1G, 1H, and 1I in accordance with some embodiments of the present disclosure.

With reference to FIG. 19, the semiconductor device 1E may have a structure similar to that illustrated in FIG. 10. Elements in FIG. 19 that are same as or similar to those in FIG. 10 are labeled with similar reference numbers and repeated descriptions are omitted.

With reference to FIG. 19, the semiconductor device 1E may include a bottom conductive layer 111. The bottom conductive layer 111 may be disposed in the substrate 101. In some embodiments, the bottom conductive layer 111 may be an impurity region configured as a source/drain. In some embodiments, the bottom conductive layer 11I may be a metal line, a conductive via, a conductive plug, or a conductive pad. The conductive structure 200 is disposed on the bottom conductive layer 111. In some embodiments, the bottom conductive layer 11I may be formed of, for example, tungsten, cobalt, zirconium, tantalum, titanium, aluminum, ruthenium, copper, metal carbides (e.g., tantalum carbide, titanium carbide, or tantalum magnesium carbide), metal nitrides (e.g., titanium nitride), transition metal aluminides, or a combination thereof.

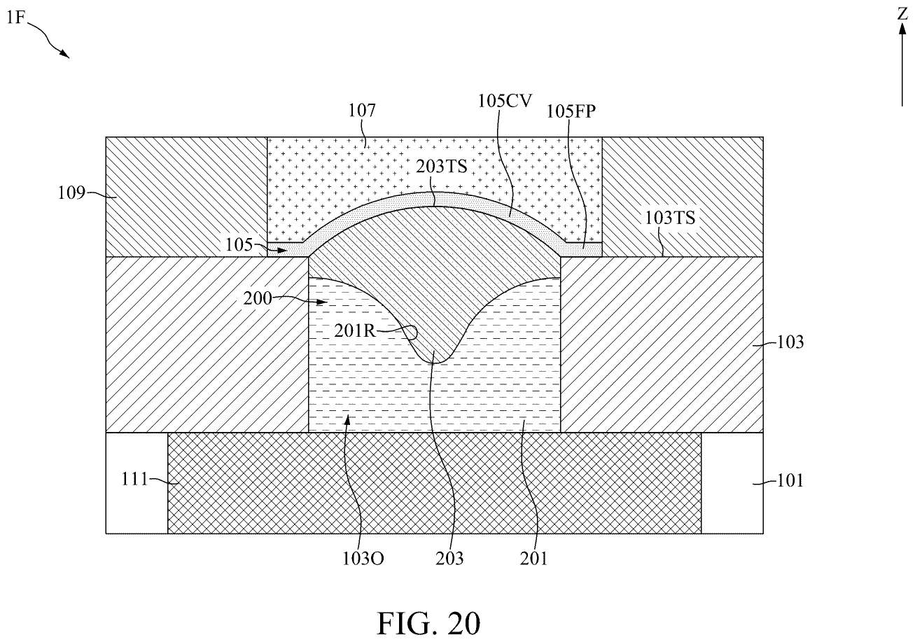

With reference to FIG. 20, the semiconductor device 1F may have a structure similar to that illustrated in FIG. 12. Elements in FIG. 20 that are same as or similar to those in FIG. 12 are labeled with similar reference numbers and repeated descriptions are omitted.

With reference to FIG. 20, the semiconductor device 1F may include a bottom conductive layer 111. The bottom conductive layer 111 may be disposed in the substrate 101. In some embodiments, the bottom conductive layer 111 may be an impurity region configured as a source/drain. In some embodiments, the bottom conductive layer 111 may be a metal line, a conductive via, a conductive plug, or a conductive pad. The conductive structure 200 is disposed on the bottom conductive layer 111. In some embodiments, the bottom conductive layer 111 may be formed of, for example, tungsten, cobalt, zirconium, tantalum, titanium, aluminum, ruthenium, copper, metal carbides (e.g., tantalum carbide, titanium carbide, or tantalum magnesium carbide), metal nitrides (e.g., titanium nitride), transition metal aluminides, or a combination thereof.

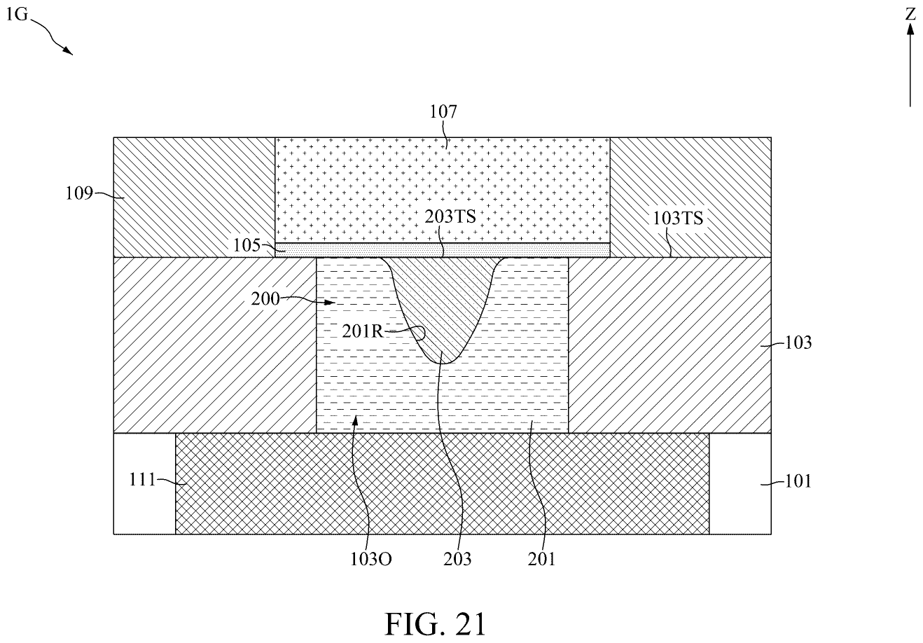

With reference to FIG. 21, the semiconductor device 1G may have a structure similar to that illustrated in FIG. 16. Elements in FIG. 21 that are same as or similar to those in FIG. 16 are labeled with similar reference numbers and repeated descriptions are omitted.

With reference to FIG. 21, the semiconductor device 1G may include a bottom conductive layer 111. The bottom conductive layer 111 may be disposed in the substrate 101. In some embodiments, the bottom conductive layer 111 may be an impurity region configured as a source/drain. In some embodiments, the bottom conductive layer 111 may be a metal line, a conductive via, a conductive plug, or a conductive pad. The conductive structure 200 is disposed on the bottom conductive layer 111. In some embodiments, the bottom conductive layer 111 may be formed of, for example, tungsten, cobalt, zirconium, tantalum, titanium, aluminum, ruthenium, copper, metal carbides (e.g., tantalum carbide, titanium carbide, or tantalum magnesium carbide), metal nitrides (e.g., titanium nitride), transition metal aluminides, or a combination thereof.

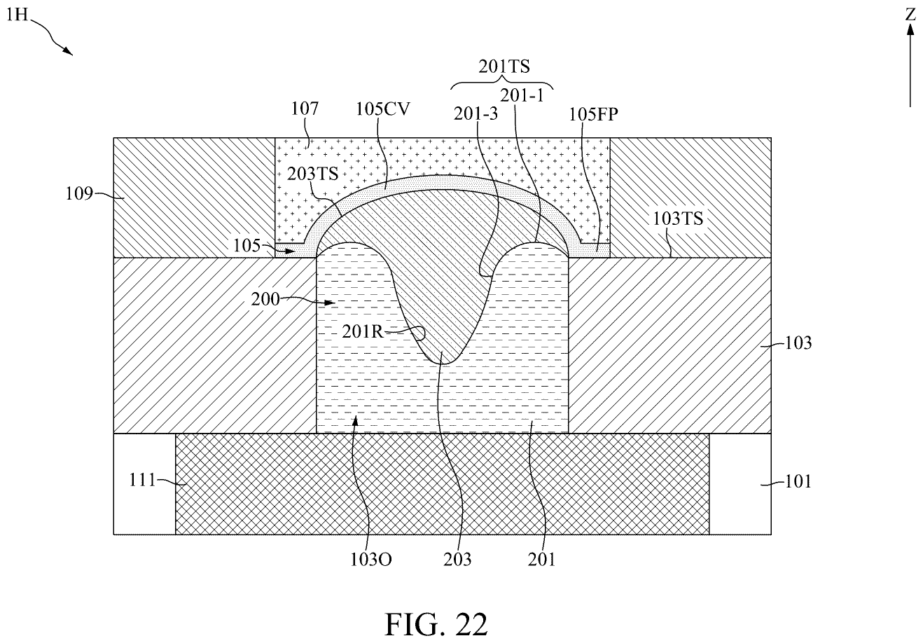

With reference to FIG. 22, the semiconductor device 1H may have a structure similar to that illustrated in FIG. 18. Elements in FIG. 22 that are same as or similar to those in FIG. 18 are labeled with similar reference numbers and repeated descriptions are omitted.

With reference to FIG. 22, the semiconductor device 1H may include a bottom conductive layer 111. The bottom conductive layer 111 may be disposed in the substrate 101. In some embodiments, the bottom conductive layer 111 may be an impurity region configured as a source/drain. In some embodiments, the bottom conductive layer 111 may be a metal line, a conductive via, a conductive plug, or a conductive pad. The conductive structure 200 is disposed on the bottom conductive layer 111. In some embodiments, the bottom conductive layer 111 may be formed of, for example, tungsten, cobalt, zirconium, tantalum, titanium, aluminum, ruthenium, copper, metal carbides (e.g., tantalum carbide, titanium carbide, or tantalum magnesium carbide), metal nitrides (e.g., titanium nitride), transition metal aluminides, or a combination thereof.

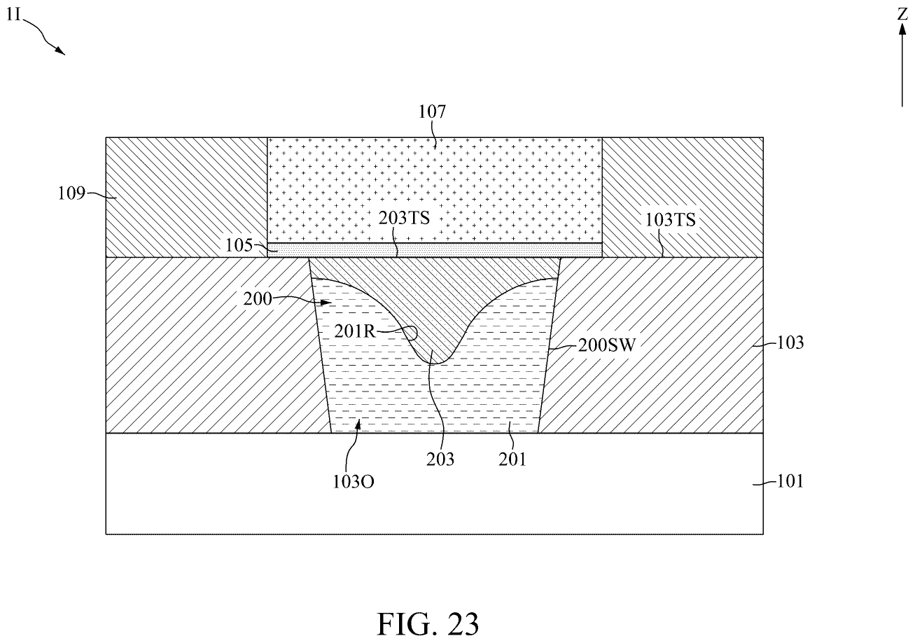

With reference to FIG. 23, the semiconductor device 1I may have a structure similar to that illustrated in FIG. 10. Elements in FIG. 23 that are same as or similar to those in FIG. 10 are labeled with similar reference numbers and repeated descriptions are omitted. In the semiconductor device 1I, a sidewall 200SW of the conductive structure 200 may be tapered.

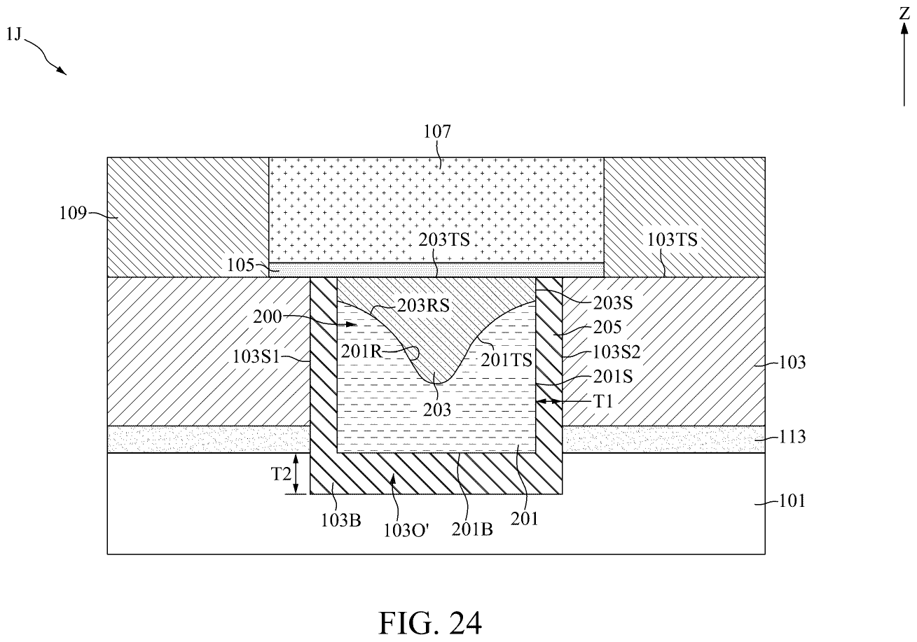

With reference to FIG. 24, a semiconductor device 1J may have a structure similar to that of the semiconductor device 1A illustrated in FIG. 10. Elements in FIG. 24 that are same as or similar to those in FIG. 10 are labeled with similar reference numbers and repeated descriptions are omitted.

With reference to FIG. 24, the semiconductor device 1J may include an epitaxial layer 113 disposed over the substrate 101 and sandwiched between the first dielectric layer 103 and the substrate 101. The epitaxial layer 113 may include conductive areas that function as source/drain regions of the semiconductor device 1J. In some embodiments, the epitaxial layer 113 includes silicon (Si). In some embodiments, the epitaxial layer 113 may be formed by an epitaxial growth method, which may include metal-organic chemical vapor deposition (MOCVD), vapor-phase epitaxy (VPE), molecular-beam epitaxy (MPE), liquid-phase epitaxy (LPE), or other suitable processes.

With reference to FIG. 24, the conductive structure 200 of the semiconductor device 1J may also include a barrier layer 205 disposed on sidewalls 103S1, 103S2 and a bottom surface 103B of a second opening 103O′, wherein the second opening 103O′ is similar to the first opening 103O in FIG. 10 except that the second opening 103O′ may penetrate the first dielectric layer 103 and the epitaxial layer 113, and may extend into the substrate 101. In other words, the conductive structure 200 includes the conductive filling layer 203, the conductive concave layer 201 and the barrier layer 205 surrounding the conductive filling layer 203 and the conductive concave layer 201. In some embodiments, the barrier layer 205 includes titanium (Ti), titanium nitride (TiN), or a combination thereof. In some embodiments, the conductive filling layer 203 and the conductive concave layer 201 are separated from the first dielectric layer 103, the epitaxial layer 113 and the substrate 101 by the barrier layer 205.

It should be noted that the barrier layer 205 has a first thickness T1 on the sidewalls 201S, 203S of the conductive concave layer 201 and the conductive filling layer 203, and the barrier layer 205 has a second thickness T2 under a bottom surface 201B of the conductive concave layer 201. In some embodiments, the barrier layer 205 is formed by an anisotropic deposition process so that the first thickness T1 is less than the second thickness T2. In some embodiments, the anisotropic deposition process includes a physical vapor deposition (PVD) process.

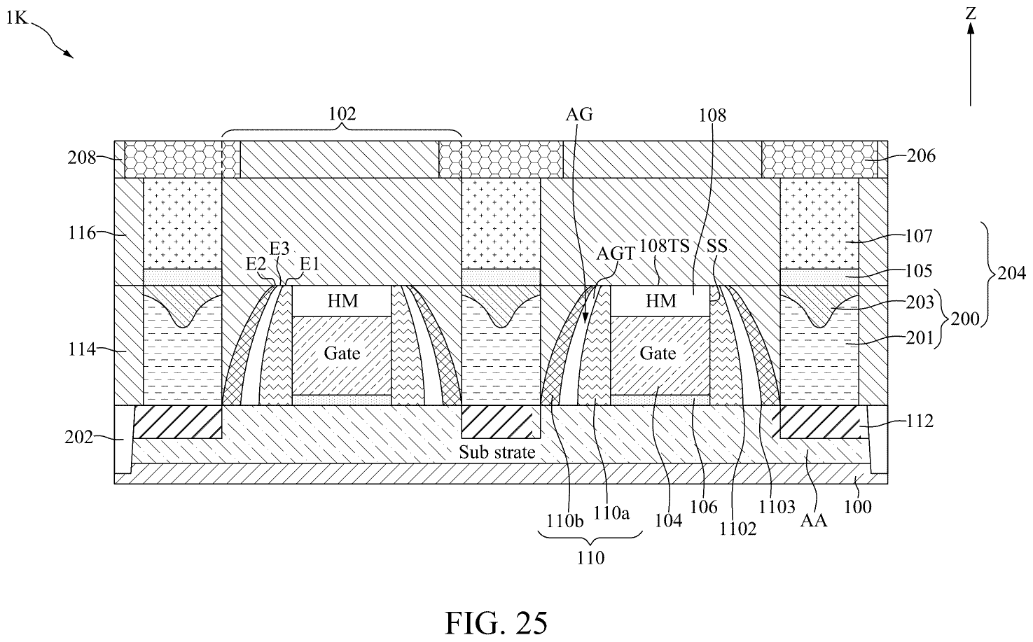

With reference to FIG. 25, a semiconductor device 1K may comprise a contact plug 204 that includes a conductive structure 200, a barrier layer 105 and a top conductive layer 107 in accordance with some embodiments of the present disclosure. The conductive structure 200, the barrier layer 105 and the top conductive layer 107 are same as or similar to those illustrated in FIG. 10, and descriptions thereof are not repeated herein.

With reference to FIG. 25, the semiconductor device 1K may be a unit cell in a memory device. In some embodiments, the memory device is a dynamic random-access (DRAM) device. In such embodiments, each unit cell (i.e., the semiconductor device 1K) may include two FETs which are of a same conductive type and which share a common source/drain node. The FETs include two of the gate structures 102 as described below. The gate structures 102 are embedded in a stack of dielectric layers (e.g., including the dielectric layer 114 and the dielectric layer 116), and separately stand on the active area AA. The active area AA of the semiconductor substrate 100 may be defined by an isolation structure 202. In some embodiments, the isolation structure 202 is a trench isolation structure extending into the semiconductor substrate 100 from a top surface thereof and laterally surrounding the active area AA. The isolation structure 202 is formed of an insulating material, such as silicon oxide, silicon nitride, silicon oxynitride, the like, or a combination thereof.

The gate structure 102 includes agate electrode 104 and agate dielectric layer 106. The gate electrode 104 is disposed on the active area AA spanning a shallow region of the semiconductor substrate 100. The gate dielectric layer 106 lies between the gate electrode 104 and the semiconductor substrate 100, such that the gate electrode 104 can be capacitively coupled to the active area AA through the gate dielectric layer 106. Although not shown, the gate electrode 104 may be formed as a line pattern, and the gate dielectric layer 106 extends along a bottom surface of the overlying gate electrode 104. The gate electrode 104 is formed of a conductive material, while the gate dielectric layer 106 is formed of a dielectric material. In some embodiments, the gate electrode 104 is formed of polysilicon, and the gate dielectric layer 106 is formed of silicon oxide. In alternative embodiments, the gate electrode 104 is formed of a metallic material, while the gate dielectric layer 106 is formed of a high-k dielectric material (e.g., a dielectric material having a dielectric constant greater than 3.9 or 7). In some embodiments, the metallic material may include tungsten, titanium, titanium nitride, aluminum, or a combination thereof, and the high-k dielectric material may include hafnium oxide, hafnium aluminum oxide, hafnium silicate, tantalum oxide, aluminum oxide, zirconium oxide, the like, or a combination thereof.

In some embodiments, the gate structure 102 further includes a hard mask 108. The hard mask 108 is disposed on the gate electrode 104. In some embodiments, the hard mask 108 functions as a shadow mask during one or more etching processes for forming the gate electrode 104 and the gate dielectric layer 106. In such embodiments, the hard mask 108 extends along a top surface of the gate electrode 104, and sidewalls of the hard mask 108 may be substantially coplanar with sidewalls of the gate electrode 104 and the gate dielectric layer 106. In order to function as the shadow mask, the hard mask 108 may be formed of a material having sufficient etching selectivity with respect to the gate electrode 104 and the gate dielectric layer 106. Alternatively, the hard mask 108 may be at least partially consumed during the etching process for forming the gate dielectric layer 106, and the material of the hard mask 108 may have less etching selectivity with respect to the gate dielectric layer 106 or may have no etching selectivity. In some embodiments, the hard mask 108 is formed of an insulating material, such as silicon oxide, silicon nitride, silicon oxynitride, silicon carbide, the like, or a combination thereof.

The gate structure 102 further includes multiple sidewall spacers 110 covering the sidewalls of the gate electrode 104. In those embodiments where the gate electrode 104 is formed in a line shape, each of the sidewall spacers 110 may include portions at opposite sides of the gate electrode 104. Further, in those embodiments where the gate electrode 104 is covered by the hard mask 108, the sidewall spacers 110 may further cover sidewalls of the hard mask 108. Moreover, in some embodiments, the sidewall spacers 110 further cover sidewalls of the gate dielectric layer 106 lying under the gate electrode 104.

The sidewall spacer 110 may include a first sidewall spacer 110a and a second sidewall spacer 110b. The sidewall spacer 110a is located between the second sidewall spacer 110b and a stacking structure including the gate electrode 104 (and the hard mask 108 and/or the gate dielectric layer 106). An air gap AG is sealed between the first sidewall spacer 110a and the second sidewall spacer 110b. Specifically, a sidewall of the first sidewall spacer 110a facing away from the gate electrode 104 defines a side boundary of the air gap AG, and a sidewall of the second sidewall spacer 110b facing toward the gate electrode 104 defines another side boundary of the air gap AG. Top surfaces of portions of the semiconductor substrate 100 between the first and second sidewall spacers 110a and 110b may define bottom boundaries of the air gaps AG. In addition, top ends of the air gaps AG may be substantially aligned with top ends of the first and second sidewall spacers 110a and 110b. Moreover, in some embodiments, a top end of the air gap AG is defined by a dielectric layer (e.g., the dielectric layer 116 as will be further described) lying above the gate structure 102. In those embodiments where each sidewall spacer 110a/110b has portions at opposite sides of the gate electrode 104, the air gap AG may have portions at opposite sides of the gate electrode 104 as well.

The air gap AG is structurally similar to one of the sidewall spacers (e.g., the first sidewall spacer 110a or the second sidewall spacer 110b) in terms of shape, and may be referred to as an air sidewall spacer or an air gate spacer. In some embodiments, a top portion of each sidewall spacer (i.e., the first sidewall spacer 110a or the second sidewall spacer 110b) is tapered toward its top end. In other words, a lateral width of each sidewall spacer (i.e., the first sidewall spacer 110a or the second sidewall spacer 110b) may decrease toward the top end of each sidewall spacer. In such embodiments, a top portion of the air gap AG may also taper toward a top end of the air gap AG, and a lateral width of the air gap AG may decrease toward the top end of the air gap AG.

The first sidewall spacer 110a and the second sidewall spacer 110b may respectively be formed of an insulating material. In some embodiments, the insulating material is a carbon-containing insulating material. The carbon-containing insulating material may include high-density carbon (HDC), silicon carbide (SiC), silicon carbonitride (SiCN) or the like. In some embodiments, the first sidewall spacer 110a may be formed of HDC or SiC, while the second sidewall spacer 110b may be formed of HDC, SiC or SiCN.

In some embodiments, multiple dielectric layers are stacked on the semiconductor substrate 100. In some embodiments, the dielectric layers may include a dielectric layer 114 laterally surrounding the gate structure 102, and a dielectric layer 116 lying on the dielectric layer 114. A top surface of the dielectric layer 114 may be substantially aligned with the top ends of the sidewall spacers 110 of the gate structure 102. Accordingly, the top surface of the dielectric layer 114 may also be substantially aligned with the top end of the air gap AG sealed between adjacent sidewall spacers 110 (e.g., the first and second sidewall spacers 110a, 110b). In those embodiments where the gate structure 102 includes the hard mask 108, the top surface of the dielectric layer 116 may be substantially aligned with a top surface of the hard mask 108. In addition, the dielectric layer 116 lying on the dielectric layer 114 covers the gate structure 102, and the dielectric layer 116 may be in contact with the top ends of the sidewall spacers 110. In those embodiments where the top portion of each sidewall spacer 110 is tapered toward its top end, the air gap AG defined between adjacent sidewall spacers 110 may also have a tapered top portion. Consequently, the top end of the air gap AG is rather narrow, and the dielectric layer 116 may be unable to enter the air gap AG through the narrow top end of the air gap AG while the dielectric layer 116 is being formed. Therefore, the narrow top end of the air gap AG can be sealed by the dielectric layer 116. The dielectric layers 114 and 116 may be respectively formed of a dielectric material. In some embodiments, the dielectric material may include silicon oxide, silicon nitride, silicon carbonitride, silicon boron nitride (SiBN), silicon oxycarbonitride (SiOCN), silicon oxynitride, silicon oxycarbide, silicon carbide, the like, or a combination thereof.

As described above, the air gap AG is sealed between adjacent ones of the sidewall spacers 110 covering opposite sidewalls of the gate electrode 104. A dielectric constant of air is approximately that of a vacuum, which may be the lowest dielectric constant for a material. Therefore, a parasitic capacitance between the gate electrode 104 and a possible conductive component next to the gate electrode 104 (e.g., a contact plug similar to the contact plug 204 as will be described with reference to FIG. 25) can be reduced as a result of the air gap AG sealed between adjacent ones of the sidewall spacers 110. Consequently, resistance-capacitance (RC) delay on signal transmission through the gate electrode 104 and the possible electrical component next to the gate electrode 104 can be effectively minimized.

Three of the source/drain structures 112 may be disposed in the active area AA. The gate structures 102 are respectively located between adjacent ones of the three source/drain structures 112. One of the source/drain structures 112 is located between the gate structures 102 and functions as the common source/drain node of the FETs. In some embodiments, the source/drain structure 112 as the common source/drain node of the FETs may be coupled to a bit line, as will be further described. The other two of the source/drain structures 112 are located at opposite sides of the gate structures 102 and may be coupled to a storage capacitor, as will be further described as well.

The contact plugs 204 respectively extend through the dielectric layers 114 and 116, to one of the source/drain structures 112, so as to establish electrical contact with the source/drain structure 112. The contact plugs 204 standing on the source/drain structure 112 between the gate structures 102 may be configured to connect such source/drain structure 112 to a bit line (as will be further described), and may be referred to as a bit line contact. This contact plug 204 (i.e., the bit line contact) is laterally spaced apart from the gate electrodes 104 of the gate structures 102 by the sidewall spacers 110 of the gate structures 102. As a result of having the air gaps AG with ultra-low dielectric constant sealed between adjacent ones of the sidewall spacers 110, a parasitic capacitance between the gate electrodes 104 and the contact plug 204 can be lowered. Therefore, an RC delay on signal transmission through the gate electrodes 104 and this contact plug 204 (i.e., the bit line contact) can be effectively minimized. In addition, the other two of the source/drain structures 112 at opposite sides of the gate structures 102 may be respectively connected to a storage capacitor (not shown) through the contact plugs 204 standing on these source/drain structures 112, and such contact plugs 204 may be referred as capacitor contacts. Similar to the bit line contact, the capacitor contacts are each laterally spaced apart from the gate electrode 104 of one of the gate structures 102 by the sidewall spacers 110 of the gate structure 102, and an RC delay on signal transmission through the gate electrode 104 and the contact plugs 204 (i.e., the capacitor contacts) can be effectively minimized as a result of the air gap AG sealed between adjacent ones of the sidewall spacers 110. The contact plugs 204 are formed of a conductive material. In some embodiments, the conductive material may include tungsten, titanium, titanium nitride, the like, or a combination thereof.

Conductive patterns 206 may respectively lie on one of the contact plugs 204. Each conductive pattern 206 is electrically connected to the underlying source/drain structure 112 through the contact plug 204 in between. In some embodiments, the conductive pattern 206 lying on and electrically connected to the source/drain structure 112 between the gate structure 102 may be a bit line. Although not shown, such conductive pattern 206 may be formed in a line shape. The other two of the conductive patterns 206 lying above and electrically connected to the source/drain structures 112 at opposite sides of the gate structures 102 may be landing pads on which storage capacitors (not shown) are disposed. Each of these conductive patterns 206 (i.e., the landing pads) may have a footprint area greater than a footprint area of the underlying contact plug 204, and thus an overlay issue of the storage capacitors can be effectively minimized. The conductive patterns 206 are formed of a conductive material. In some embodiments, the conductive material may include copper, titanium, titanium nitride, the like, or a combination thereof. In some embodiments, the conductive patterns 206 are formed in an additional dielectric layer 208. In such embodiments, the conductive patterns 206 may be laterally surrounded by the additional dielectric layer 208. The additional dielectric layer 208 may be formed of the dielectric material for forming the dielectric layers 114, 116. Alternatively, the dielectric material for forming the additional dielectric layer 208 may be different from the dielectric material for forming the dielectric layers 114, 116. The dielectric material for forming the additional dielectric layer 208 may include, for example, silicon oxide, silicon nitride, silicon carbonitride, silicon boron nitride (SiBN), silicon oxycarbonitride (SiOCN), silicon oxynitride, silicon oxycarbide, silicon carbide, the like, or a combination thereof.

One aspect of the present disclosure provides a semiconductor device including a substrate; a conductive structure including a conductive concave layer disposed on the substrate and comprising a top surface having a V-shaped cross-sectional profile, a conductive filling layer disposed on the conductive concave layer, and a first barrier layer covering sidewalls of the conductive concave layer and the conductive filling layer and a bottom surface of the conductive concave layer; and a top conductive layer disposed on the conductive structure. The conductive structure is disposed in the substrate and protrudes from the substrate. A surface of the conductive filling layer is concave with respect to the substrate. The conductive filling layer includes germanium or silicon germanium.

Another aspect of the present disclosure provides a semiconductor device including a stacking structure disposed on a semiconductor substrate; a first sidewall spacer and a second sidewall spacer covering a sidewall of the stacking structure; and a contact plug disposed between a pair of the stacking structures. An air gap is sealed between the first and second sidewall spacers. Topmost ends of the first sidewall spacer, the air gap, and the second sidewall spacer, and a top surface of the stacking structure, are coplanar. A top portion of the air gap is tapered toward the topmost end of the air gap.

Another aspect of the present disclosure provides a method for fabricating a semiconductor device including providing a substrate; forming an epitaxial layer on the substrate; forming a first dielectric layer on the epitaxial layer; forming a first opening in the first dielectric layer, the epitaxial layer, and the substrate; forming a conductive concave layer in the first opening; forming a conductive filling layer on the conductive concave layer and in the first opening; and forming a top conductive layer on the conductive filling layer. A top surface of the conductive concave layer has a V-shaped cross-sectional profile. The conductive concave layer and the conductive filling layer together form a conductive structure. The conductive filling layer comprises germanium or silicon germanium.

Due to the design of the semiconductor device of the present disclosure, a resistance of the conductive structure may be reduced by employing the conductive filling layer including germanium. As a result, a performance of the semiconductor device may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate;
a conductive structure disposed in the substrate and protruding from the substrate, comprising:
a conductive concave layer disposed over the substrate and comprising a top surface having a V-shaped cross-sectional profile;
a conductive filling layer disposed on the conductive concave layer, wherein a surface of the conductive filling layer is concave with respect to the substrate; and
a first barrier layer covering sidewalls of the conductive concave layer and the conductive filling layer, and covering a bottom surface of the conductive concave layer; and
a top conductive layer disposed over the conductive structure;
wherein the conductive filling layer comprises germanium or silicon germanium.

2. The semiconductor device of claim 1, wherein the conductive concave layer comprises silicon and/or germanium with substantially no oxygen and no nitrogen.

3. The semiconductor device of claim 2, further comprising a first dielectric layer disposed over the substrate, wherein the conductive structure penetrates through the first dielectric layer.

4. The semiconductor device of claim 3, further comprising an epitaxial layer disposed between the substrate and the first dielectric layer.

5. The semiconductor device of claim 4, further comprising a second barrier layer disposed between the conductive structure and the top conductive layer.

6. The semiconductor device of claim 5, wherein the first dielectric layer comprises a dielectric material comprising oxygen atoms and/or nitrogen atoms.

7. The semiconductor device of claim 6, wherein the second barrier layer comprises titanium, titanium nitride, tantalum, tantalum nitride, or a combination thereof.

8. The semiconductor device of claim 7, wherein the top conductive layer comprises aluminum, tungsten, copper, or a combination thereof.

9. The semiconductor device of claim 8, wherein a width of the conductive concave layer and a width of the conductive filling layer are substantially equal.

10. The semiconductor device of claim 9, wherein a top surface of the conductive filling layer and a top surface of the first dielectric layer are substantially coplanar.

11. The semiconductor device of claim 10, wherein the conductive filling layer and the conductive concave layer are separated from the first dielectric layer, the epitaxial layer and the substrate by the first barrier layer.

12. The semiconductor device of claim 1, wherein the first barrier layer comprises titanium (Ti), titanium nitride (TiN), or a combination thereof.

13. The semiconductor device of claim 12, wherein a thickness of the first barrier layer on sidewalls of the conductive concave layer and the conductive filling layer is less than a thickness of the first barrier layer under the bottom surface of the conductive concave layer.

14. The semiconductor device of claim 13, wherein the first barrier layer is formed by an anisotropic deposition process.

15. The semiconductor device of claim 14, further comprising a second dielectric layer disposed on the first dielectric layer and covering the top conductive layer.
